(19) United States
(12) Patent Application Publication
(10) Pub. No.: US 2024/0201813 A1
(43) Pub. Date: Jun. 20, 2024

(54) TOUCH SUBSTRATE, DISPLAY APPARATUS AND DISPLAY SYSTEM

(71) Applicants: Beijing BOE Sensor Technology Co., Ltd., Beijing (CN); BOE TECHNOLOGY GROUP CO., LTD., Beijing (CN)

(72) Inventors: Feng LIU, Beijing (CN); Shoujin CAI, Beijing (CN); Cheng LI, Beijing (CN); Chuncheng CHE, Beijing (CN); Tiansheng LI, Beijing (CN); Lin ZHOU, Beijing (CN); Yingzi WANG, Beijing (CN)

(21) Appl. No.: 18/565,132

(22) PCT Filed: Jun. 3, 2021
(86) PCT No.: PCT/CN2021/098187

§ 371 Date: Nov. 29, 2023

(51) Int. Cl. G06F 3/042; G02F 1/1333; G02F 1/1335

(52) U.S. Cl. CPC G06F 3/0421; G02F 1/13338; G02F 1/133512

(57) ABSTRACT

A touch substrate, a display apparatus and a display system are provided. The touch substrate includes: a base substrate including a photosensitive region; and a plurality of photosensitive pixels in an array in the photosensitive region. Each photosensitive pixel includes a plurality of non-visible light sensors and at least one transistor, and each transistor is connected to at least two non-visible light sensors of the plurality of non-visible light sensors.

### TECHNICAL FIELD

The present disclosure relates to the field of display technology, and in particular to a touch substrate, a display apparatus and a display system.

### BACKGROUND

With the continuous development of communication technology, computer technology and electronic technology, mobile communication is developing from Human to Human (H2H) communication to Human to Machine (H2M) communication and Machine to Machine (M2M) communication, and the Internet of Everything becomes a necessary trend for the development of the mobile communication.

The Internet of Things (IoT) has been emerged in this context, and is considered to be the third wave of the world information industry after the computer and the Internet. The Internet of Things adopts the means of the informatization technology to promote the comprehensive upgrade of human life and production service, and has a wide application and development prospect and a strong industrial driving capability. European and American countries have brought development of the Internet of Things into the whole informatization strategy, and China has also definitely brought the development of the Internet of Things into the Outline of the National Medium and Long Term Science and Technology Development Program (2006-2020) and the 2050 National Industry Roadmap of China.

In the general background of the Internet of Things, the human-computer interaction appears to be particularly important, and the human-computer interaction is not only the infrastructure of the Internet of Things, but also the final target of the Internet of Things, for achieving the Internet of Everything serving human beings. The human-computer interaction refers to the fact that a user communicates with and operates a system through a human-computer interaction interface. A small object, such as a play button of a radio, and a big object, such as a dashboard on a plane or a control room of a power plant, are both used at every moment. There are various ways for implementing the human-computer interaction, such as a touch control based on a pressure, a resistance or a capacitance, or a face recognition based on the light, or a sound-based ultrasound, or a tactile feedback based on an electrostatic feedback or the like. The touch interaction of the consumer products, such as mobile phones and televisions, is widely applied at present, but the technology has a certain limitation. That is, the interaction can be realized only by a contact-type touch control, which limits the range of application and cannot realize the remote touch interaction. A light touch control has been emerged in this context.

### SUMMARY

Embodiments of the present disclosure provide a touch substrate, a display apparatus and a display system as below.

In one aspect, embodiments of the present disclosure provide a touch substrate, including: a base substrate including a photosensitive region; and a plurality of photosensitive pixels in an array in the photosensitive region, each photosensitive pixel includes a plurality of non-visible light sensors and at least one transistor, and each transistor is connected to at least two non-visible light sensors of the plurality of non-visible light sensors.

Optionally, in the touch substrate provided by the embodiments of the present disclosure, the touch substrate further includes: a plurality of gate lines and a plurality of data lines, the plurality of gate lines extend in a first direction, and the plurality of data lines extend in a second direction; and each photosensitive pixel is divided into four regions by one gate line and one data line intersecting with each other, and one transistor and at least two non-visible light sensors electrically connected to the transistor are in at least one region.

Optionally, in the touch substrate provided by the embodiments of the present disclosure, each photosensitive pixel includes two transistors, and one transistor and at least two non-visible light sensors electrically connected to the transistor are in each of two regions in a diagonal direction.

Optionally, in the touch substrate provided by the embodiments of the present disclosure, two non-visible light sensors in each of the two regions are arranged along the diagonal direction.

Optionally, in the touch substrate provided by the embodiments of the present disclosure, the touch substrate further includes a bias layer on a side of the plurality of non-visible light sensors away from the base substrate, the bias layer includes a bias line extending along the second direction and leads extending along the first direction; each non-visible light sensor includes a first electrode between a layer where the at least one transistor is located and the bias layer; and in each photosensitive pixel, the first electrodes of the plurality of non-visible light sensors are electrically connected to the bias line through different leads.

Optionally, in the touch substrate provided by the embodiments of the present disclosure, each non-visible light sensor further includes a photosensitive layer between layers where the first electrode and the transistor are located, and in direct contact with the first electrode; a ratio of an area of the photosensitive layer in each non-visible light sensor to an area of each photosensitive pixel is in a range from 1:2500 to 9:2500.

Optionally, in the touch substrate provided by the embodiments of the present disclosure, non-visible light sensors in an array along the first direction and the second direction are in any one region.

Optionally, in the touch substrate provided by the embodiments of the present disclosure, one transistor, and non-visible light sensors in an array along the first direction and the second direction are in only one region.

Optionally, in the touch substrate provided by the embodiments of the present disclosure, the touch substrate further includes a bias layer on a side of the plurality of non-visible light sensors away from the base substrate, the bias layer includes a bias line extending along the second direction and leads extending along the first direction; each non-visible light sensor includes a first electrode between a layer where the at least one transistor is located and the bias layer; and in each photosensitive pixel, the first electrodes of the plurality of non-visible light sensors in an array are connected in series, and are electrically connected to the bias line through the same lead.

Optionally, in the touch substrate provided by the embodiments of the present disclosure, each non-visible light sensor further includes a photosensitive layer between layers where the first electrode and the transistor are located, and in direct contact with the first electrode; a ratio of an area of the photosensitive layer in each non-visible light sensor to an area of each photosensitive pixel is in a range from 1:10000 to 1:900.

Optionally, in the touch substrate provided by the embodiments of the present disclosure, an orthographic projection of the bias line on the base substrate overlaps with an orthographic projection of a channel region of one transistor of each photosensitive pixel on the base substrate.

Optionally, in the touch substrate provided by the embodiments of the present disclosure, each non-visible light sensor further includes a second electrode between a layer where a source electrode or a drain electrode of the transistor is located and the photosensitive layer, opposite to the first electrode, and in direct contact with the photosensitive layer; and the second electrodes of all the non-visible light sensors in each region are connected in series, and are electrically connected to the source electrode or the drain electrode of the transistor.

Optionally, in the touch substrate provided by the embodiments of the present disclosure, in any region, in the first direction, a distance between an orthographic projection of the transistor on the base substrate and an orthographic projection of the data line on the base substrate is less than a distance between an orthographic projection of each non-visible light sensor on the base substrate and the orthographic projection of the data line on the base substrate.

Optionally, in the touch substrate provided by the embodiments of the present disclosure, a center-to-center distance between two adjacent photosensitive pixels is in a range from 3 mm to 5 mm.

Optionally, in the touch substrate provided by the embodiments of the present disclosure, the touch substrate further includes a non-visible light antireflection film on a side of the plurality of non-visible light sensors close to a liquid crystal display module; the non-visible light antireflection film covers only the plurality of non-visible light sensors.

In another aspect, embodiments of the present disclosure further provide a display apparatus, including: a backlight source; a liquid crystal display module on a light outgoing side of the backlight source; and a touch substrate on a side of the liquid crystal display module opposite to a display surface of the liquid crystal display module; and the touch substrate is the touch substrate provided by the embodiments of the present disclosure.

Optionally, in the display apparatus provided by the embodiments of the present disclosure, the liquid crystal display module includes a black matrix, and each photosensitive pixel includes four non-visible light sensors along the diagonal direction, and pitches of the four non-visible light sensors satisfy the following relationships:

$${d}_{1} \geq A + \frac{C \times n}{3} ; {d}_{2} \leq ( \frac{C}{3} - A ) + \frac{C \times n}{3} ; {d}_{3} \geq D + C \times n ; {d}_{4} \leq C - D + C \times n ;$$

where d₁ denotes a minimum distance between the two non-visible light sensors in each region in the first direction; d₂ denotes a maximum distance between the two non-visible light sensors in each region in the first direction; d₃ denotes a minimum distance between the two non-visible light sensors in each region in the second direction; d₄ denotes a maximum distance between the two non-visible light sensors in each region in the second direction; C denotes a side length of each display pixel in the liquid crystal display module; A denotes a width of the black matrix in the first direction; D denotes a width of the black matrix in the second direction, and n denotes a positive integer.

Optionally, in the display apparatus provided by the embodiments of the present disclosure, the liquid crystal display module includes a black matrix, and each photosensitive pixel includes the plurality of non-visible light sensors in an array, and pitches of the plurality of non-visible light sensors in an array satisfy the following relationship: d₅≥D; where d₅ denotes a maximum distance between adjacent ones of the plurality of non-visible light sensors in an array in each of the first direction and the second direction, and D denotes a width of the black matrix in the second direction.

Optionally, in the display apparatus provided by the embodiments of the present disclosure, the liquid crystal display module includes a plurality of display pixels, and a ratio of an area of each display pixel to an area of each photosensitive pixel is in a range from 1:1 to 2:1.

Optionally, in the display apparatus provided by the embodiments of the present disclosure, the display apparatus further includes: a reflector, a diffusion sheet, and a light guide plate; the reflector is on a side of the touch substrate away from the liquid crystal display module; and the diffusion sheet is between the touch substrate and the liquid crystal display module; and the light guide plate is between the diffusion sheet and the liquid crystal display module.

In another aspect, embodiments of the present disclosure further provide a display system, including a display apparatus and a non-visible light emitter, and the display apparatus is the display apparatus provided by the embodiments of the present disclosure.

### BRIEF DESCRIPTION OF DRAWINGS

FIG. 1 is a schematic diagram of a structure of a touch substrate according to embodiments of the present disclosure;

FIG. 2 is a schematic diagram of a structure of a photosensitive pixel of FIG. 1;

FIG. 3 is a schematic diagram of another structure of a photosensitive pixel of FIG. 1;

FIG. 4 is a schematic diagram of another structure of a photosensitive pixel of FIG. 1;

FIG. 5 is a schematic diagram of another structure of a photosensitive pixel of FIG. 1;

FIG. 6 is a cross-sectional view of a structure of a photosensitive pixel;

FIG. 7 is a schematic diagram of a structure of a display apparatus according to embodiments of the present disclosure;

FIG. 8 is a schematic diagram of a size of a display pixel;

FIG. 9 is a schematic diagram of a size of a photosensitive pixel;

FIG. 10 is a schematic diagram of matching of sizes of a photosensitive pixel and a display pixel; and.

FIG. 11 is a schematic diagram of a structure of a display system according to embodiments of the present disclosure.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It should be noted that the sizes and shapes of various elements shown in the drawings are not necessarily drawn to scale and are merely schematic representations of the present disclosure. Like or similar elements or elements having like or similar functions are denoted by like or similar reference symbols throughout the various figures. It is to be understood that the described embodiments are only a few, not all of, embodiments of the present disclosure. All other embodiments, which can be derived by a person skilled in the art from the embodiments of the present disclosure without any creative effort, are within the protective scope of the present disclosure.

Unless defined otherwise, technical or scientific terms used herein shall have the ordinary meaning as understood by one of ordinary skill in the art to which the present disclosure belongs. The terms “first”, “second”, and the like used in the description and the claims of the present disclosure are not intended to indicate any order, quantity, or importance, but rather are used for distinguishing one element from another. The term “comprising/comprise”, “including/includes”, or the like, means that the element or item preceding the term contains the element or item listed after the term and its equivalent, but does not exclude other elements or items. The terms “inner”, “outer”, “upper/on”, “lower/under”, “left”, “right”, and the like are used only for indicating relative positional relationships, and when the absolute position of an object being described is changed, the relative positional relationships may also be changed accordingly.

The remote interaction can be realized by adopting a near infrared light sensor, has a huge application prospect in fields such as the smart screen (such as TV & whiteboard), or Gaming MNT or the like, and has technical characteristics including the accurate positioning in a millimeter level, and a response speed in a millisecond level, and the display flexibility and the like, and realize the soaring accurate non-delay positioning operation and the non-contact handwriting effect.

In some embodiments, the near infrared light sensor is provided between a liquid crystal display module of a liquid crystal display apparatus and a backlight source, so that the display and the remote real-time interaction can be realized. However, as the research is advanced, it is found in the present disclosure that the near infrared light sensor using the amorphous silicon (a-si) material is sensitive to both the near infrared light band and the visible light band, and have a strong absorption for the light in the near infrared light band and the visible light band, and particularly, have an absorption peak of the green light in the 550 nm band, which is up to 80%. Therefore, when the near infrared light sensor is arranged between the liquid crystal display module of the liquid crystal display apparatus and the backlight source, the display effect is adversely affected by an excessively large area of the near infrared light sensor.

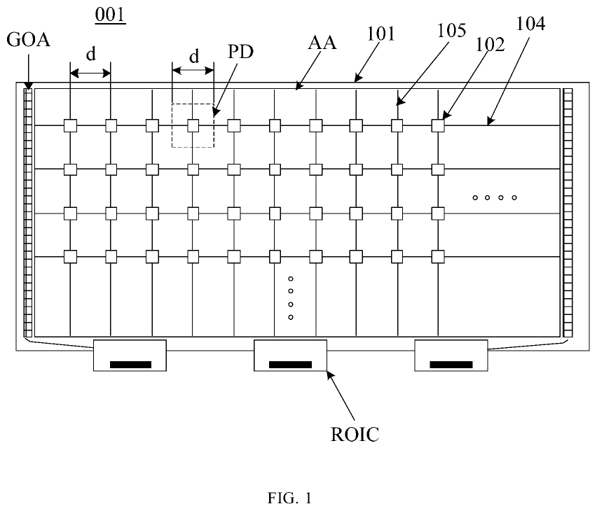

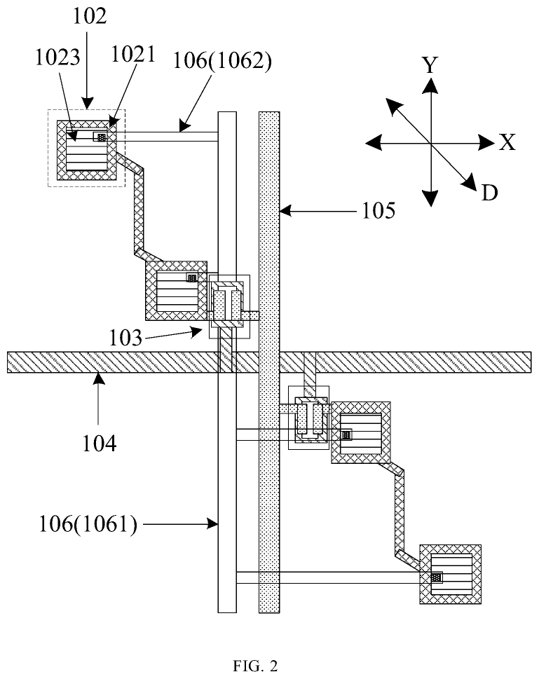

In order to at least solve the above technical problems in the related art, embodiments of the present disclosure provide a touch substrate 001, which is particularly suitable for the field of the remote large-sized non-visible light (e.g., near infrared light) interaction technology. As shown in FIG. 1 and FIG. 2, the touch substrate may include:

A base substrate 101 including a photosensitive region AA;

A plurality of photosensitive pixels PD arranged in an array in the photosensitive region AA, each photosensitive pixel PD includes a plurality of non-visible light sensors 102 and at least one transistor 103, and each transistor 103 is connected to at least two non-visible light sensors 102 of the plurality of non-visible light sensors 102.

In the display apparatus provided by the embodiments of the present disclosure, the plurality of non-visible light sensors 102 independent from each other are arranged in each photosensitive pixel PD, so that a photosensitive region of each photosensitive pixel PD is the sum of photosensitive regions of the plurality of non-visible light sensors 102; and with the same photosensitive region, an area of each non-visible light sensor 102 in the present disclosure can be reduced to 1/m of an area of a non-separate non-visible light sensor 102 (m is the total number of the non-visible light sensors 102 in each photosensitive pixel PD), thereby reducing the influence of the excessively large area of the non-visible light sensor 102 on the uniformity of the backlight, and effectively improving the display effect.

In some embodiments, as shown in FIG. 2 to FIG. 5, the touch substrate provided in the embodiments of the present disclosure may further include: a plurality of gate lines 104 and a plurality of data lines 105, and the plurality of gate lines 104 extend in a first direction X, and the plurality of data lines 105 extend in a second direction Y;

Each photosensitive pixel PD is divided into four regions by one gate line 104 and one data line 105 intersecting with each other, and one transistor 103 and at least two non-visible light sensors 102 electrically connected to the transistor 103 are provided in at least one region.

In some embodiments, in the touch substrate provided in the embodiments of the present disclosure, as shown in FIGS. 2 to 4, each photosensitive pixel PD may include two transistors 103, and one transistor 103 and at least two non-visible light sensors 102 electrically connected to the transistor 103 are arranged in each of two regions in a diagonal direction D.

The two transistors 103 of each photosensitive pixel PD are controlled by the gate line 104 and the data line 105 dividing the photosensitive pixel PD into the four regions, so that the two transistors 103 may be turned on or off simultaneously. Compared with a solution in which one transistor 103 is included in each photosensitive pixel PD, the charge reading time can be reduced to the half by adopting two transistors 103 in the present disclosure, so that an operating frequency can be increased to be higher than 120 Hz, and the user experience is optimized.

In addition, by arranging one transistor 103 and at least two non-visible light sensors 102 electrically connected thereto in each of two regions in the diagonal direction D, the distribution uniformity of the transistors 103 and the non-visible light sensors 102 in the photosensitive pixels PD can be improved, so that the influence on the uniformity of the backlight can be reduced.

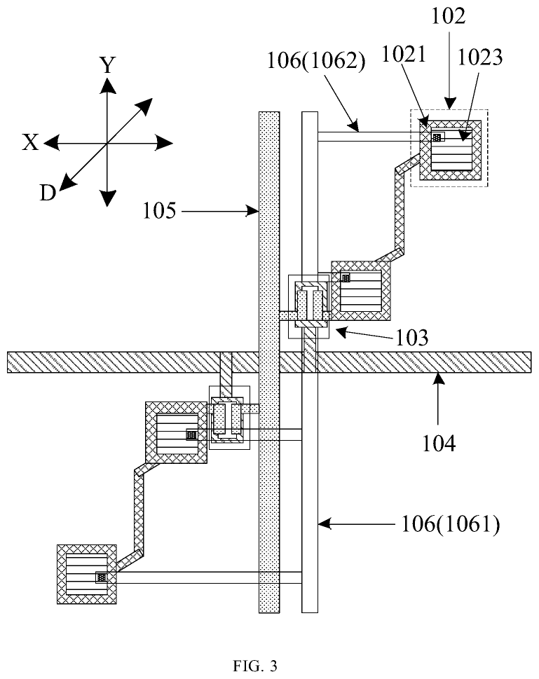

In some embodiments, as shown in FIG. 2 and FIG. 3, in the touch substrate provided in the embodiments of the present disclosure, any one of the two regions in the diagonal direction D may include two non-visible light sensors 102 arranged along the diagonal direction D, and equivalently, in the two regions in the diagonal direction D, the four non-visible light sensors 102 may be arranged in four rows and four columns, so that the four non-visible light sensors 102 are arranged in a staggered manner in the first direction X and the second direction Y, thereby ensuring that the four non-visible light sensors 102 are distributed uniformly in the photosensitive pixel PD, which not only can reduce the influence of the non-visible light sensors 102 on the uniformity of the backlight, but also is beneficial for the non-visible light sensors 102 to receive non-visible light signals (for example, near infrared light of about 820 nm), so as to achieve (balance) both the display effect and the touch interaction effect.

In some embodiments, as shown in FIG. 2 and FIG. 3, the touch substrate provided in the embodiments of the present disclosure may further include a bias layer 106 located on a side of the non-visible light sensors 102 away from the base substrate 101, and the bias layer 106 may include a bias line 1061 extending along the second direction Y and leads 1062 extending along the first direction X.

Each non-visible light sensor 102 may include a first electrode 1021 located between a layer where the transistor 103 is located and the bias layer 106.

In each photosensitive pixel PD, the first electrodes 1021 of the non-visible light sensors 102 are electrically connected to the bias line 1061 through different leads 1062, so that the bias line 1061 applies driving signals to the different non-visible light sensors 102 through the different leads 1062.

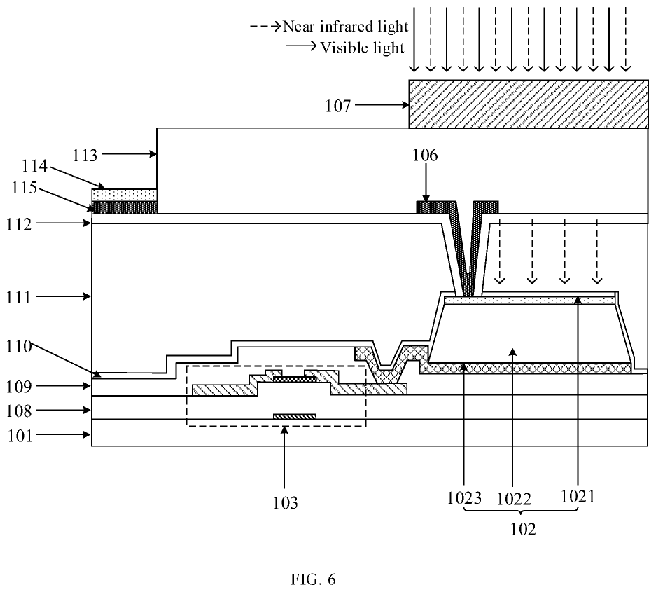

In some embodiments, in the touch substrate provided in the embodiments of the present disclosure, as shown in FIG. 2, FIG. 3 and FIG. 6, each non-visible light sensor 102 may further include a photosensitive layer 1022 located between layers where the first electrode 1021 and the transistor 103 are located, and in direct contact with the first electrode 1021. Since the number of the non-visible light sensors 102 included in each photosensitive pixel PD is small, an area of the photosensitive layer 1022 included in each non-visible light sensor 102 may be large. For example, a ratio of an area of the photosensitive layer 1022 included in each non-visible light sensor 102 to an area of each photosensitive pixel PD may be in a range from 1:2500 to 9:2500, so as to achieve both the display effect and the touch interaction effect.

In some embodiments, as shown in FIG. 1, a bisector of a center-to-center distance d between two adjacent photosensitive pixels PD (a distance d between centers of two adjacent photosensitive pixels PD) is a boundary of the photosensitive pixels PD, and an area of each photosensitive pixel PD may be equal to a square of the center-to-center distance d between two adjacent photosensitive pixels PD. For example, the center-to-center distance d between two adjacent photosensitive pixels PD is in a range from 3 mm to 5 mm, and accordingly, the area of each photosensitive pixel PD is in a range from 3 mm×3 mm to 5 mm×5 mm. The area of the photosensitive layer 1022 included in each non-visible light sensor 102 may be in a range from 100 μm×100 μm to 180 μm×180 μm under the condition that the ratio of the area of the photosensitive layer 1022 included in each non-visible light sensor 102 to the area of each photosensitive pixel PD is in a range from 1:2500 to 9:2500.

In some embodiments, the photosensitive layer 1022 may include a P-type semiconductor layer and an N-type semiconductor layer which are stacked together; or may include an N-type semiconductor layer, an intrinsic semiconductor layer I, and a P-type semiconductor layer which are stacked sequentially, and the intrinsic semiconductor layer I may have a thickness greater than that of the P-type semiconductor layer and that of the N-type semiconductor layer.

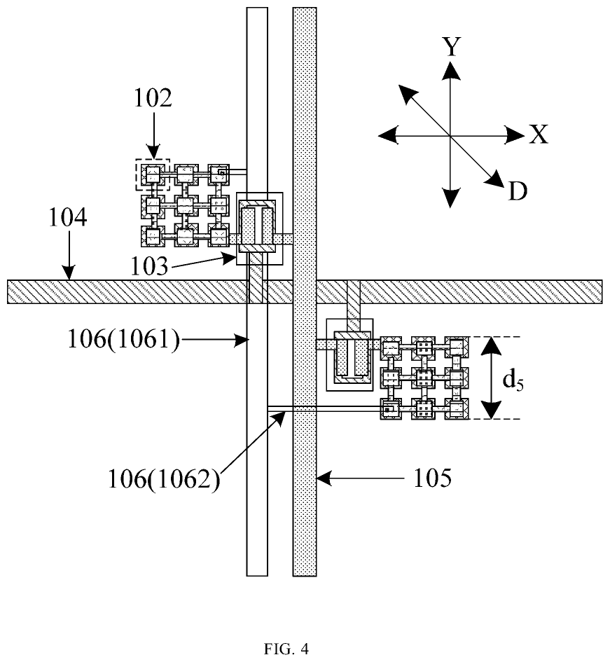

In some embodiments, in the touch substrate provided in the embodiments of the present disclosure, as shown in FIG. 4, any one of the two regions in the diagonal direction D may include a plurality of non-visible light sensors 102 arranged in an array along the first direction X and the second direction Y. Specifically, in FIG. 4, the plurality of non-visible light sensors 102 in the any one of two regions in the diagonal direction D form a 3×3 square array.

The plurality of non-visible light sensors 102 forming the square array can not only meet the requirements of the photosensitive pixel PD, but also have gaps among the plurality of non-visible light sensors 102, so that an aperture ratio of the photosensitive pixel PD can reach more than 50%, and the adverse effect of the excessively large area of the non-visible light sensor 102 on the display is reduced to a great extent.

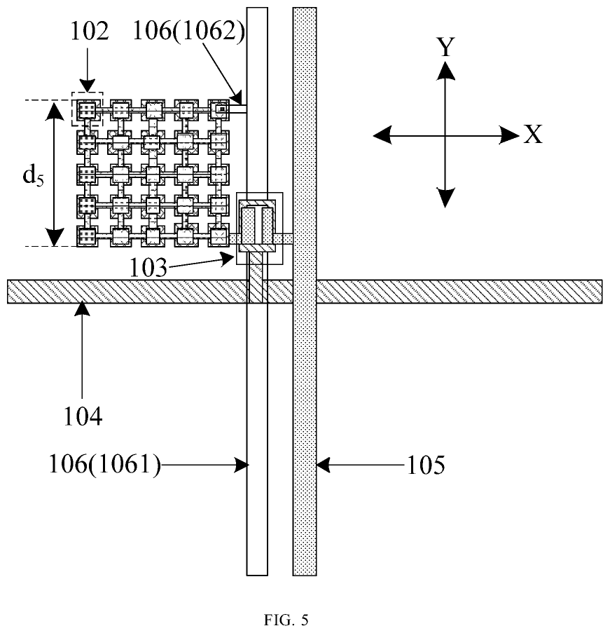

In some embodiments, in the touch substrate provided in the embodiments of the present disclosure, in order to achieve both the display effect and the touch interaction effect, as shown in FIG. 5, only one region may be provided with a transistor 103 and a plurality of non-visible light sensors 102 arranged in an array along the first direction X and the second direction Y, and specifically, a square array of 5×5 is formed in FIG. 5.

In some embodiments, as shown in FIG. 4 to FIG. 6, the touch substrate provided in the embodiment of the present disclosure may further include a bias layer 106 located on a side of the non-visible light sensors 102 away from the base substrate 101, and the bias layer 106 may include the bias line 1061 extending along the second direction Y and the lead 1062 extending along the first direction X;

Each non-visible light sensor 102 includes the first electrode 1021 located between the layer where the transistor 103 is located and the bias layer 106;

In each photosensitive pixel PD, the first electrodes 1021 of the plurality of non-visible light sensors 102 arranged in an array are arranged to be connected in series, and are electrically connected to the bias line 1061 through the same lead 1062, so as to uniformly apply the driving signals to the plurality of non-visible light sensors 102 arranged in an array through the bias line 1061.

In some embodiments, as shown in FIGS. 4 to 6, in the touch substrate provided in the embodiment of the present disclosure, each of the plurality of non-visible light sensors 102 arranged in an array may further include the photosensitive layer 1022, the photosensitive layer 1022 may be located between the layers where the first electrode 1021 and the transistor 103 are located, and may be in direct contact with the first electrode 1021, and the ratio of the area of the photosensitive layer 1022 included in each non-visible light sensor 102 to the area of each photosensitive pixel is in a range from 1:10000 to 1:900.

The number of the non-visible light sensors 102 included in the square array is large, and the area of each non-visible light sensor 102 with the above ratio is small, so that the transmittance of the backlight can be ensured. In some embodiments, each photosensitive pixel PD may have an area in a range from 3 mm×3 mm to 5 mm×5 mm, and the photosensitive layer 1022 included in each non-visible light sensor 102 may have an area in a range from 50 μm×50 μm to 100 μm×100 μm.

In some embodiments, in the touch substrate provided in the embodiments of the present disclosure, as shown in FIG. 2 to FIG. 6, each non-visible light sensor 102 may further include a second electrode 1023 located between a layer where a source electrode or a drain electrode of the transistor 103 is located and the photosensitive layer 1022, arranged opposite to the first electrode 1021, and in direct contact with the photosensitive layer 1022. The first electrode 1021 in direct contact with the photosensitive layer 1022 is separately arranged, so that the first electrode 1021 can be ensured to be flat, and leakage current can be reduced. In addition, the second electrodes 1023 of all the non-visible light sensors 102 of each region may be arranged to be connected in series, and are electrically connected to the source electrode or the drain electrode of the transistor 103.

In some embodiments, in the touch substrate provided in the embodiments of the present disclosure, as shown in FIGS. 2 to 5, an orthographic projection of the bias line 1061 on the base substrate 101 overlaps with an orthographic projection of a channel region of one transistor 103 of each photosensitive pixel PD on the base substrate 101, so as to reduce an influence of the light on the performance of the transistor 103.

In some embodiments, in the touch substrate provided in the embodiments of the present disclosure, as shown in FIGS. 2 to 5, in any region, in the first direction X, a distance between an orthographic projection of the transistor 103 on the base substrate 101 and an orthographic projection of the data line 105 on the base substrate 101 is less than a distance between an orthographic projection of each non-visible light sensor 102 on the base substrate 101 and the orthographic projection of the data line 105 on the base substrate 101, and equivalently, a region where the transistor 103 is located is between a region where the data line 105 is located and a region where the non-visible light sensors 102 are located, so that the source electrode or the drain electrode of the transistor 103 is electrically connected to the data line 105 and the second electrodes 1023 of the non-visible light sensors 102, respectively.

A near infrared light emitter emits near infrared light with a wavelength in a range from 800 nm to 900 nm, a size of a light spot is limited to be less than or equal to 5 mm, and the divergence of the light spot is not more than 5% at a distance less than or equal to 5 m. A transmitting distance and a receiving distance are each limited to be in a range of 0 m to 10 m from the screen. If each distance is too great, there is little significance according to the use scene. A transmitting power of the near infrared light emitter is limited to be less than or equal to 1 mw, so that the household injury prevention requirement (it is reported that the near infrared light with a high intensity can injure the iris of the eyes of a person) is met, and a signal intensity of a receiving end can be met. The non-visible near infrared light emitted in this way is projected on the touch substrate, and a large light spot necessarily (completely) covers the non-visible light sensors 102, so that the conversion of an optical signal to an electrical signal can be realized by the non-visible light sensors 102.

Based on this, in the touch substrate provided in the embodiment of the present disclosure, each non-visible light sensor 102 may be a near infrared light sensor, and as shown in FIG. 1, the center-to-center distance d between two adjacent photosensitive pixels PD may be in a range from 3 mm to 5 mm, to match a size of a light spot of a non-visible light emitter (e.g., the near infrared light emitter).

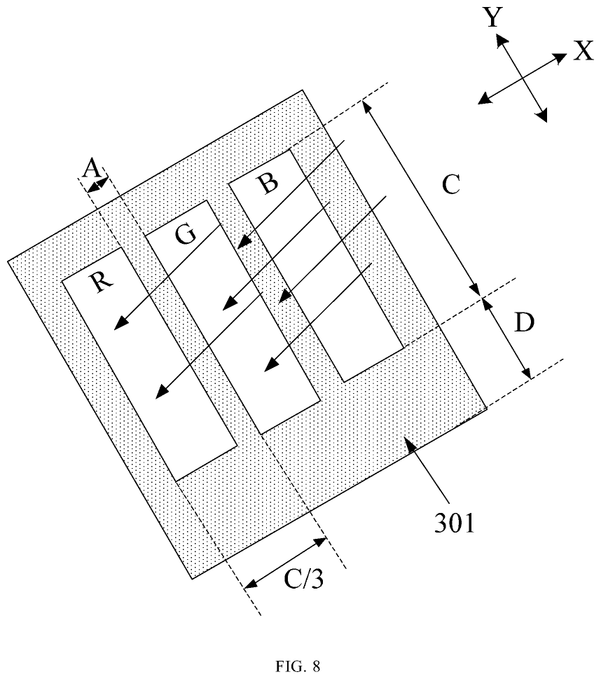

In some embodiments, the photosensitive layer 1022 made of the amorphous silicon (a-si) material is sensitive to both the near infrared light band and the visible light band and have a strong absorption for the light in the near infrared light band and the visible light band. Therefore, in the touch substrate provided in the embodiment of the present disclosure, in order to prevent the ambient light from interfering the touch effect and prevent the non-visible light sensors 102 from being overexposed due to receiving the ambient light, as shown in FIG. 8, the touch substrate 001 may further include: a non-visible light antireflection film 107 located on a side of the non-visible light sensors 102 close to a liquid crystal display module 003. In order to increase the transmittance for the backlight, the non-visible light antireflection film 107 may cover only the non-visible light sensors 102. In some embodiments, a material of the non-visible light antireflection film 107 may be a black matrix (BM) material, which can selectively transmit the non-visible light (e.g., the near infrared light) and block the non-visible light in other bands (e.g., a non-near infrared band) and the visible light.

It should be noted that in the touch substrate provided in the embodiment of the present disclosure, as shown in FIG. 1, the touch substrate may further include: gate driving circuits GOA for providing scanning signals to the plurality of gate lines 104, and read circuits ROIC electrically connected to the plurality of data lines 105; the gate driving circuits GOA are located on a left frame and a right frame, and a width of each gate driving circuit GOA is in a range from 1 mm to 2 mm; the number of the read circuits ROIC increases as the size of the product increases.

In addition, as shown in FIG. 6, the touch substrate 001 may further include: a gate insulating layer 108, a first insulating layer 109, a first protective layer 110, a planarization layer 111, a second insulating layer 112, a second protective layer 113, an indium tin oxide layer 114, and a bias terminal (Pad) 115, and the indium tin oxide layer 114 can protect the bias terminal 115 from corrosion by water, oxygen, and the like in the air. Other essential components in the touch substrate 001 should be understood by one of ordinary skill in the art and thus, are not described herein, and should not be construed as a limitation to the present disclosure.

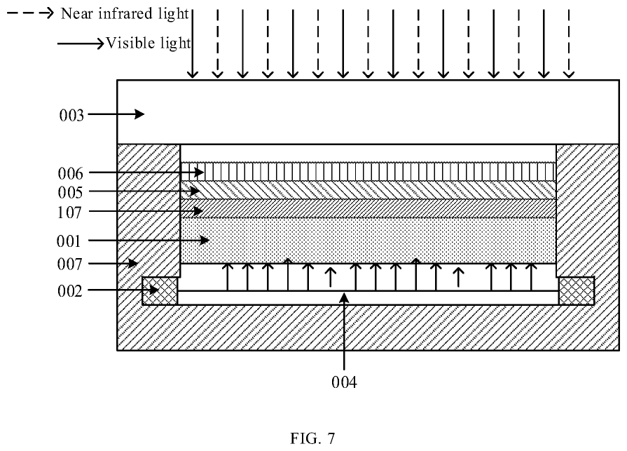

Based on the same inventive concept, an embodiment of the present disclosure further provides a display apparatus, including: as shown in FIG. 7, a touch substrate 001, a backlight source 002 and a liquid crystal display module 003, where the liquid crystal display module 003 is located on the light outgoing side of the backlight source 002, the touch substrate 001 is located on a side of the liquid crystal display module 003 opposite to a display surface of the liquid crystal display module 003, and the touch substrate 001 is the touch substrate provided in the embodiment of the present disclosure. As the principle of the display apparatus for solving the problems is similar to that of the touch substrate, the implementation of the display apparatus provided by the embodiment of the present disclosure can refer to the implementation of the touch substrate provided by the embodiment of the present disclosure, and repeated descriptions are omitted.

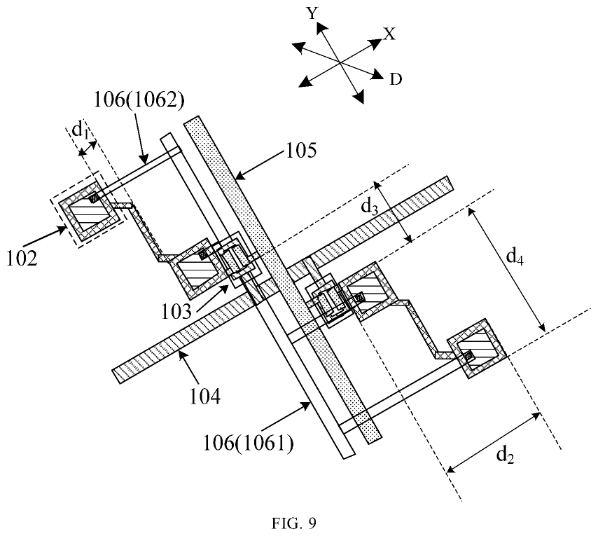

In some embodiments, in the display apparatus provided in the embodiment of the present disclosure, as shown in FIG. 7, the liquid crystal display module 003 is located above the touch substrate 001, so that a black matrix 301 of the liquid crystal display module 003 can shield the non-visible light sensors 102 to a certain extent. Therefore, in order to maximize the areas of the non-visible light sensors 102 exposed by the black matrix 301 and therefore maximize the amount of the non-visible light (for example, the near infrared light) received by each photosensitive pixel PD, as shown in FIGS. 8 and 9, when each photosensitive pixel PD includes four non-visible light sensors 102 arranged along the diagonal direction D, the four non-visible light sensors 102 may satisfy the following distance relationships:

$${d}_{1} \geq A + \frac{C \times n}{3} ;$$

$${d}_{2} \leq ( \frac{C}{3} - A ) + \frac{C \times n}{3} ;$$

$${d}_{3} \geq D + C \times n ;$$

$${d}_{4} \leq C - D + C \times n ;$$

where d₁ denotes a minimum distance in the first direction X between the two non-visible light sensors 102 in each region; d₂ denotes a maximum distance in the first direction X between the two non-visible light sensors 102 in each region; d₃ denotes a minimum distance in the second direction Y between the two non-visible light sensors 102 in each region; d₄ denotes a maximum distance in the second direction Y between the two non-visible light sensors 102 in each region; C denotes a side length of each display pixel P included in the liquid crystal display module 003; A denotes a width of the black matrix 301 in the first direction X; D denotes a width of the black matrix 301 in the second direction Y, and n denotes a positive integer.

By taking a 55-inch liquid crystal display module 003 as an example, an area of each display pixel P is 315 μm×315 μm, i.e., C is equal to 315 μm; the width A of the black matrix 301 in the first direction X is in a range from 14 μm to 19 μm; and the width B of the black matrix 301 in the second direction Y is in a range from 65 μm to 97 μm, then the following can be obtained according to the above formula: d₁≥19+105×n (μm), d₂≤86+105×n (μm), d₃≥97+315×n (μm), d₄≤218+315×n (μm).

In some embodiments, in the display apparatus provided by the embodiments of the present disclosure, as shown in FIGS. 4, 5, and 8, when each photosensitive pixel PD includes the plurality of non-visible light sensors 102 arranged in an array, in order to maximize the area of the non-visible light sensors 102 exposed by the black matrix 301, the plurality of non-visible light sensors 102 arranged in an array satisfy the following distance relationship:

$${d}_{5} \geq D ;$$

where d₅ denotes a maximum distance between two farthest ones of the plurality of non-visible light sensors 102 arranged in an array in each of the first direction X and the second direction Y, and D denotes the width of the black matrix 301 in the second direction Y.

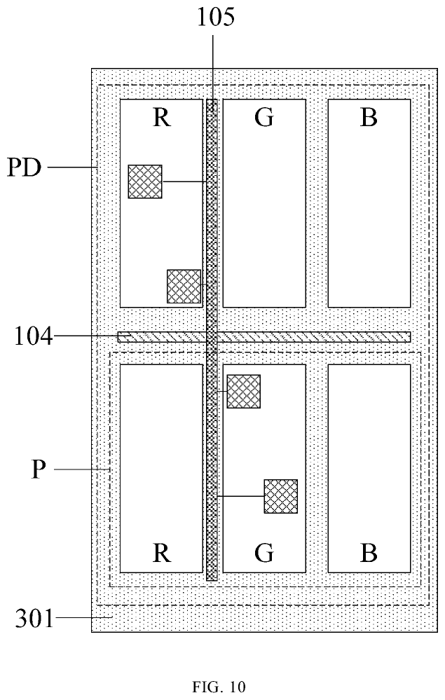

In some embodiments, in the display apparatus provided by the embodiments of the present disclosure, as shown in FIG. 10, the liquid crystal display module 003 may include a plurality of display pixels P, and a ratio of an area of each display pixel P to an area of each photosensitive pixel PD may be in a range from 1:1 to 2:1, in other words, the area of each photosensitive pixel PD may be equal to the area of one display pixel P to a sum of the areas of two display pixels P, so as to achieve both the display effect and the touch interaction effect.

In a specific implementation, each display pixel P may include a red sub-pixel R, a green sub-pixel G, a blue sub-pixel B, and the like, which is not limited herein.

In some embodiments, as shown in FIG. 7, in the display apparatus provided in the embodiments of the present disclosure, the display apparatus may further include: a reflector 004, a diffusion sheet 005, and a light guide plate 006; the reflector 004 may be located on a side of the touch substrate 001 away from the liquid crystal display module 003; and the diffusion sheet 005 may be located between the touch substrate 001 and the liquid crystal display module 003; and the light guide plate 006 may be located between the diffusion sheet 005 and the liquid crystal display module 003, and the backlight source 002 may be located on a side of the reflector 004. The reflector 004, the diffusion sheet 005 and the light guide plate 006 may cooperatively control the light emitted from the backlight source 002 to be uniformly incident to the liquid crystal display module 003.

In some embodiments, in the display apparatus provided in the embodiments of the present disclosure, the liquid crystal display module 003 may be a twisted nematic (TN) type liquid crystal display, an advanced dimension switch (ADS) type liquid crystal display, a high-advanced dimension switch (HADS) type liquid crystal display, an in-plane switch (IPS) type liquid crystal display, or the like, which is not particularly limited herein. Other essential components in the liquid crystal display module 003 should be understood by one of ordinary skill in the art and thus, are not described herein, and should not be construed as a limitation to the present disclosure.

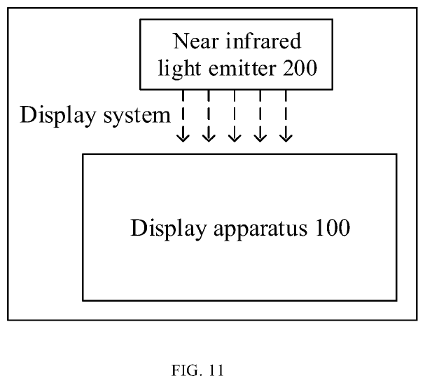

Based on the same inventive concept, the embodiments of the present disclosure further provide a display system, as shown in FIG. 11, which may include a display apparatus 100 and a non-visible light emitter 200, and the display apparatus 100 is the above display apparatus provided by the embodiments of the present disclosure. Because the principle of the display system for solving the problems is similar to that of the display apparatus, the implementation of the display system provided by the embodiments of the present disclosure can refer to the implementation of the display apparatus provided by the embodiments of the present disclosure, and repeated descriptions are omitted.

In a specific implementation, the non-visible light emitter 200 may be a near infrared light emitter; each non-visible light sensor 102 may be a near infrared light sensor; non-visible near infrared light emitted by the near infrared light emitter is projected on the display apparatus 100, and a large light spot covers the near infrared light sensor, so that an optical signal is converted into an electrical signal by the near infrared light sensor, and a touch position is determined by the electrical signal, thereby realizing the remote touch interaction.

It will be apparent to one of ordinary skill in the art that, various changes and modifications may be made in the embodiments of the present disclosure without departing from the spirit and scope of the present disclosure. Thus, if such changes and modifications of the embodiments of the present disclosure are within the scope of the claims and their equivalents of the present disclosure, the present disclosure is also intended to encompass such changes and modifications.

1. A touch substrate, comprising:
a base substrate comprising a photosensitive region; and
a plurality of photosensitive pixels arranged in an array in the photosensitive region,
wherein each photosensitive pixel comprises a plurality of non-visible light sensors and at least one transistor, and each transistor is connected to at least two non-visible light sensors of the plurality of non-visible light sensors.

2. The touch substrate of claim 1, further comprising a plurality of gate lines and a plurality of data lines,
wherein the plurality of gate lines extend in a first direction, and the plurality of data lines extend in a second direction; and
each photosensitive pixel is divided into four regions by one gate line and one data line intersecting with each other, and at least one region of the four regions each is provided with one transistor and at least two non-visible light sensor electrically connected to the transistor.

3. The touch substrate of claim 2, wherein each photosensitive pixel comprises two transistors, and one transistor and at least two non-visible light sensors electrically connected to the transistor are in each of two regions in a diagonal direction.

4. The touch substrate of claim 3, wherein two non-visible light sensors in each of the two regions are arranged along the diagonal direction.

5. The touch substrate of claim 4, further comprising a bias layer on a side of the plurality of non-visible light sensors away from the base substrate,
wherein the bias layer comprises a bias line extending along the second direction and leads extending along the first direction;
each non-visible light sensor comprises a first electrode between a layer where the at least one transistor is located and the bias layer; and
in each photosensitive pixel, the first electrodes of the plurality of non-visible light sensors are electrically connected to the bias line through different leads.

6. The touch substrate of claim 5, wherein each non-visible light sensor further comprises a photosensitive layer between layers where the first electrode and the transistor are located, and in direct contact with the first electrode; and
a ratio of an area of the photosensitive layer in each non-visible light sensor to an area of each photosensitive pixel is in a range from 1:2500 to 9:2500.

7. The touch substrate of claim 3, wherein non-visible light sensors in each of the two regions are arranged in an array along the first direction and the second direction.

8. The touch substrate of claim 2, wherein each photosensitive pixel comprises one transistor, and this transistor and non-visible light sensors, electrically connected to this transistor, arranged in an array along the first direction and the second direction are in only one region of the four regions.

9. The touch substrate of claim 7, further comprising a bias layer on a side of the plurality of non-visible light sensors away from the base substrate,
wherein the bias layer comprises a bias line extending along the second direction and leads extending along the first direction;
each non-visible light sensor comprises a first electrode between a layer where the at least one transistor is located and the bias layer; and
in each photosensitive pixel, the first electrodes of the plurality of non-visible light sensors in an array are arranged to be connected in series, and are electrically connected to the bias line through a same lead.

10. The touch substrate of claim 9, wherein each non-visible light sensor further comprises a photosensitive layer between layers where the first electrode and the transistor are located, and in direct contact with the first electrode; and
a ratio of an area of the photosensitive layer in each non-visible light sensor to an area of each photosensitive pixel is in a range from 1:10000 to 1:900.

11. The touch substrate of claim 5, wherein an orthographic projection of the bias line on the base substrate overlaps with an orthographic projection of a channel region of one transistor of each photosensitive pixel on the base substrate.

12. The touch substrate of claim 6, wherein each non-visible light sensor further comprises a second electrode between a layer where a source electrode or a drain electrode of the transistor is located and the photosensitive layer, opposite to the first electrode, and in direct contact with the photosensitive layer; and
the second electrodes of all the non-visible light sensors in each region are arranged to be connected in series, and are electrically connected to the source electrode or the drain electrode of the transistor.

13. The touch substrate of claim 2, wherein in each of the at least one region, in the first direction, a distance between an orthographic projection of the transistor on the base substrate and an orthographic projection of the data line on the base substrate is less than a distance between an orthographic projection of each non-visible light sensor on the base substrate and the orthographic projection of the data line on the base substrate.

14. (canceled)

15. The touch substrate of claim 1, further comprising: a non-visible light antireflection film on a side of the plurality of non-visible light sensors away from the base substrate;
wherein the non-visible light antireflection film covers only the plurality of non-visible light sensors.

16. A display apparatus, comprising:
a backlight source;
a liquid crystal display module on a light outgoing side of the backlight source; and
a touch substrate on a side of the liquid crystal display module opposite to a display surface of the liquid crystal display module;
wherein the touch substrate comprises:
a base substrate comprising a photosensitive region; and
a plurality of photosensitive pixels arranged in an array in the photosensitive region,
wherein each photosensitive pixel comprises a plurality of non-visible light sensors and at least one transistor, and each transistor is connected to at least two non-visible light sensors of the plurality of non-visible light sensor.

17. The display apparatus of claim 16, wherein the liquid crystal display module comprises a black matrix, and each photosensitive pixel comprises four non-visible light sensors along the diagonal direction, and the four non-visible light sensors satisfy following distance relationships:
$${d}_{1} \geq A + \frac{C \times n}{3} ;$$
$${d}_{2} \leq ( \frac{C}{3} - A ) + \frac{C \times n}{3} ;$$
$${d}_{3} \geq D + C \times n ;$$
$${d}_{4} \leq C - D + C \times n ;$$
where d₁ denotes a minimum distance, in the first direction, between the two non-visible light sensors in the at least one region; d₂ denotes a maximum distance, in the first direction, between the two non-visible light sensors in the at least one region; d₃ denotes a minimum distance, in the second direction, between the two non-visible light sensors in the at least one region; d₄ denotes a maximum distance, in the second direction, between the two non-visible light sensors in the at least one region; C denotes a side length of each display pixel in the liquid crystal display module; A denotes a width of the black matrix in the first direction; D denotes a width of the black matrix in the second direction, and n denotes a positive integer.

18. The display apparatus of claim 16, wherein the liquid crystal display module comprises a black matrix, and each photosensitive pixel comprises the plurality of non-visible light sensors arranged in an array, and the plurality of non-visible light sensors arranged in an array satisfy a following distance relationship:
$${d}_{5} \geq D ;$$
where d₅ denotes a maximum distance, in each of the first direction and the second direction, between two farthest ones of the plurality of non-visible light sensors arranged in an array, and D denotes a width of the black matrix in the second direction.

19. The display apparatus of claim 16, wherein the liquid crystal display module comprises a plurality of display pixels, and a ratio of an area of each display pixel to an area of each photosensitive pixel is in a range from 1:1 to 2:1.

20. The display apparatus of claim 16, further comprising: a reflector, a diffusion sheet, and a light guide plate;
wherein the reflector is on a side of the touch substrate away from the liquid crystal display module;
the diffusion sheet is between the touch substrate and the liquid crystal display module; and
the light guide plate is between the diffusion sheet and the liquid crystal display module.

21. A display system, comprising a display apparatus and a non-visible light emitter,
wherein the display apparatus is the display apparatus of claim 16.
